(19) United States
(12) Patent Application Publication
(10) Pub. No.: US 2026/0106613 A1
(43) Pub. Date: Apr. 16, 2026

(54) Contactor Starting Circuit and Contactor Control System

(71) Applicant: Tyco Electronics (Shanghai) Co., Ltd., Shanghai (CN)

(72) Inventors: Jimmy Wang, Shanghai (CN); Xinhui (Robert) Mao, Shanghai (CN); Yisong Wu, Shanghai (CN); Lizhong Wang, Shanghai (CN); Yong Jia, Shanghai (CN)

(73) Assignee: Tyco Electronics (Shanghai) Co., Ltd., Shanghai (CN)

(21) Appl. No.: 19/354,153

(22) Filed: Oct. 9, 2025

(30) Foreign Application Priority Data
Oct. 10, 2024 (CN) 202411413642.4

(51) Int. Cl. H03K 17/687; H03K 3/017

(52) U.S. Cl. CPC H03K 17/6871; H03K 3/017

(57) ABSTRACT

A contactor starting circuit includes a boost circuit increasing an input power supply voltage, a sampling circuit connected to an output end of the boost circuit, a drive circuit connected to the output end of the boost circuit, and a microcontroller. The output voltage of the boost circuit is higher than the input power supply voltage. The sampling circuit collects the output voltage. The drive circuit provides a stable starting voltage to a contactor coil. The microcontroller controls the drive circuit based on the output voltage collected by the sampling circuit. When the output voltage reaches a predetermined voltage, the microcontroller controls the drive circuit to provide the stable starting voltage to the contactor coil, such that the contactor coil has a constant starting current during a starting phase. A duration of the constant starting current is not less than a predetermined time.

### CROSS-REFERENCE TO RELATED APPLICATION

This application claims the benefit of the filing date under 35 U.S.C. § 119 (a)-(d) of Chinese Patent Application No. CN202411413642.4 filed on Oct. 10, 2024, the whole disclosure of which is incorporated herein by reference.

### FIELD OF THE INVENTION

The present invention relates to a starting circuit and a control system and, more particularly, to a contactor starting circuit and a contactor control system comprising the contactor starting circuit.

### BACKGROUND OF THE INVENTION

The core competitive advantage of high-voltage contactors is their small size, which matches customers' demand for miniaturization applications. However, the starting current of the coil of miniaturized high-voltage contactors is relatively high, usually requiring 3A or even higher. However, many customers have limited power supply, with a supply current generally not exceeding 1.5A, which cannot meet the current requirements for coil start-up. This results in the inability of existing high-voltage contactors to be applied in many customers' products.

### SUMMARY OF THE INVENTION

A contactor starting circuit includes a boost circuit increasing an input power supply voltage, a sampling circuit connected to an output end of the boost circuit, a drive circuit connected to the output end of the boost circuit, and a microcontroller. The output voltage of the boost circuit is higher than the input power supply voltage. The sampling circuit collects the output voltage. The drive circuit provides a stable starting voltage to a contactor coil. The microcontroller controls the drive circuit based on the output voltage collected by the sampling circuit. When the output voltage reaches a predetermined voltage, the microcontroller controls the drive circuit to provide the stable starting voltage to the contactor coil, such that the contactor coil has a constant starting current during a starting phase. A duration of the constant starting current is not less than a predetermined time.

### BRIEF DESCRIPTION OF DRAWINGS

The invention will now be described by way of example with reference to the accompanying figures, of which:

FIG. 1 is a functional block diagram of a contactor starting circuit according to an exemplary embodiment;

FIG. 2 is a circuit diagram of the contactor starting circuit of FIG. 1; and

FIG. 3 is a functional block diagram of a contactor control system according to an exemplary embodiment.

### DETAILED DESCRIPTION

Exemplary embodiments of the present disclosure will be described hereinafter in detail with reference to the attached drawings, wherein like reference numerals refer to like elements. The present disclosure may, however, be embodied in many different forms and should not be construed as being limited to the embodiments set forth herein; rather, these embodiments are provided so that the present disclosure will be thorough and complete, and will fully convey the concept of the disclosure to those skilled in the art.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

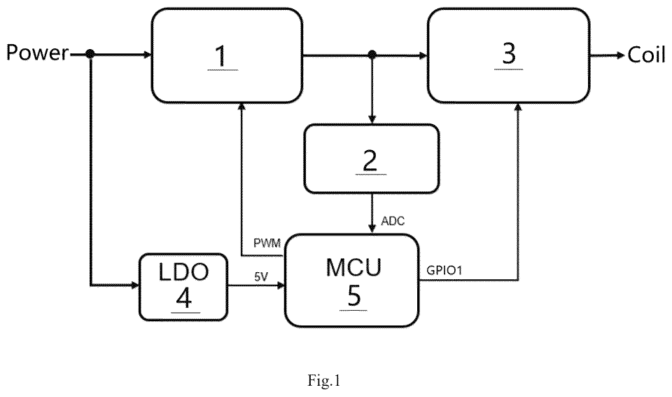

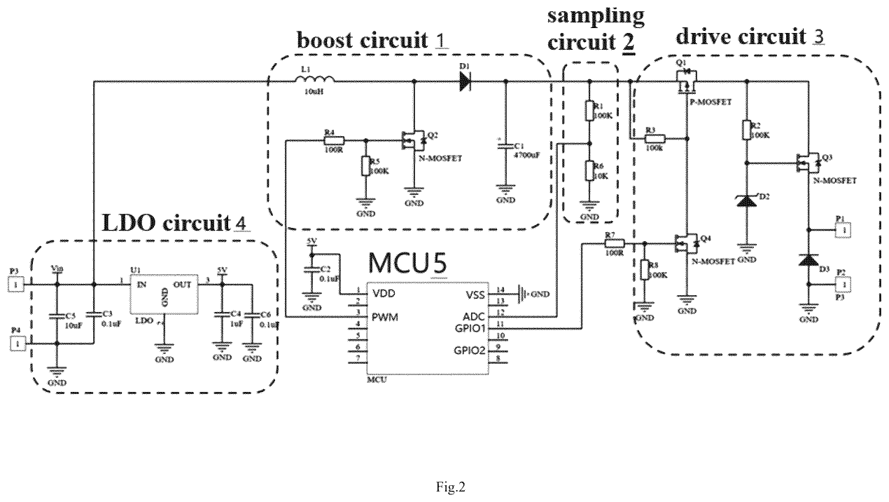

An exemplary embodiment of a contactor starting circuit will now be described with reference to FIGS. 1-2. The contactor starting circuit of a contactor includes a boost circuit 1, a sampling circuit 2, a drive circuit 3, and a microcontroller 5. The boost circuit 1 is used to increase an input power supply voltage Vin, so that an output voltage Vout of boost circuit 1 is higher than the power supply voltage Vin. The sampling circuit 2 is connected to an output end of the boost circuit 1, and used to collect the output voltage Vout of the boost circuit 1. The drive circuit 3 is connected to the output end of the boost circuit 1, and used to provide stable starting voltage to a contactor coil. The microcontroller 5 is suitable for controlling the drive circuit 3 based on the output voltage Vout of the boost circuit 1 collected by the sampling circuit 2. When the output voltage Vout of the boost circuit 1 reaches a predetermined voltage, the microcontroller 5 controls the drive circuit 3 to provide a stable starting voltage to the contactor coil, so that the contactor coil has a constant starting current during a starting phase. The duration of this constant starting current is not less than a predetermined time.

When the output voltage Vout of the boost circuit 1 does not reach the predetermined voltage, the microcontroller 5 controls the drive circuit 3 to cut off the electrical connection between the output end of the boost circuit 1 and the contactor coil. When the output voltage Vout of the boost circuit 1 reaches the predetermined voltage, the microcontroller 5 controls the drive circuit 3 to connect the electrical connection between the output end of the boost circuit 1 and the contactor coil.

The microcontroller 5 is also adapted to control the boost circuit 1 based on the output voltage Vout collected by sampling circuit 2. When the output voltage Vout of the boost circuit 1 does not reach the predetermined voltage, the microcontroller 5 controls the boost circuit 1 to continue to increase the output voltage Vout. When the output voltage Vout of the boost circuit 1 reaches the predetermined voltage, the microcontroller 5 controls the boost circuit 1 to stop raising the output voltage Vout.

The contactor starting circuit can ensure that the starting current of the contactor coil is not less than 3 amperes and the duration of the starting current is not less than 60 milliseconds.

As shown in FIG. 2, the boost circuit 1 includes an inductor L1, an N-type MOS transistor Q2, a diode D1, and a capacitor C1. One end of the inductor L1 is used to connect to the power supply. The drain of the N-type MOS transistor Q2 is connected to the other end of the inductor L1, its source is grounded, and its gate is connected to one output port of the microcontroller 5. The positive electrode of the diode D1 is connected to the other end of the inductor L1 and the drain of the N-type MOS transistor Q2. One end of the capacitor C1 is connected to the negative electrode of the diode D1, and the other end is grounded. One end of the inductor L1 serves as the input end of boost circuit 1, and one end of the capacitor C1 serves as the output end of the boost circuit 1.

The capacitance value of capacitor C1 can be calculated according to the following formula: C1=I*T/(Vout-Vin). In the formula, C1 is the capacitance value of the capacitor C1, I is the starting current of the contactor coil, T is the duration of the starting current of the contactor coil, Vout is the output voltage of the boost circuit 1, and Vin is the input power supply voltage.

As shown in FIG. 2, one output port of microcontroller 5 is used to output a PWM wave to the gate of the N-type MOS transistor Q2, so that the maximum output voltage Vmax of the boost circuit 1 can be controlled by adjusting the duty cycle D of the PWM wave.

The maximum output voltage Vmax of the boost circuit 1 can be calculated according to the following formula: Vmax=Vin/(1−D). In the formula Vmax is the maximum output voltage of the boost circuit 1, Vin is the input power supply voltage, and D is the duty cycle of the PWM wave.

As shown in FIG. 2, the boost circuit 1 further comprises a resistor R4 and a resistor R5. One end of the resistor R4 is connected to the one output port of the microcontroller 5, and the other end is connected to the gate of the N-type MOS transistor Q2. One end of resistor R5 is connected to one end of resistor R4 and the one output port of microcontroller 5, while the other end is grounded.

As shown in FIG. 2, the sampling circuit 2 includes a resistor R1 and a resistor R6. One end of the resistor R1 is connected to the output end of the boost circuit 1. One end of the resistor R6 is connected to the other end of the resistor R1, and the other end is grounded. An analog-to-digital converter (ADC) of the microcontroller 5 is connected to the other end of the resistor R1 and one end of the resistor R6 to obtain a sampling voltage V1. The output voltage Vout of the boost circuit 1 can be calculated according to the following formula: Vout=V1*(R1+R6)/R6. In the formula, Vout is the output voltage of the boost circuit 1, and V1 is the sampling voltage obtained by the microcontroller 5.

As shown in FIG. 2, the drive circuit 3 includes a P-type MOS transistor Q1, a resistor R3, an N-type MOS transistor Q4, a resistor R2, and a voltage regulator diode D2. The source of the P-type MOS transistor Q1 is connected to the output end of the boost circuit 1. One end of the resistor R3 is connected to the output end of the boost circuit 1, and the other end is connected to the gate of the P-type MOS transistor Q1. The drain of the N-type MOS transistor Q4 is connected to the other end of the resistor R3 and the gate of the P-type MOS transistor Q1, with its source grounded. One end of the resistor R2 is connected to the drain of the P-type MOS transistor Q1. The negative electrode of the voltage regulator diode D2 is connected to the other end of the resistor R2, and its positive electrode is grounded. A general-purpose input/output port GPIO1 of the microcontroller 5 is connected to the gate of the N-type MOS transistor Q4. The voltage regulator diode D2 provides a stable driving voltage.

When the output voltage Vout of the boost circuit 1 does not reach the predetermined voltage, the general-purpose input/output port GPIO1 of the microcontroller 5 outputs a low level to the gate of the N-type MOS transistor Q4, causing both the N-type MOS transistor Q4 and the P-type MOS transistor Q1 to be in a cut-off state, thereby cutting off the electrical connection between the drive circuit 3 and the boost circuit 1. When the output voltage Vout of the boost circuit 1 reaches the predetermined voltage, the general-purpose input/output port GPIO1 of the microcontroller 5 outputs a high level to the gate of the N-type MOS transistor Q4, causing both the N-type MOS transistor Q4 and the P-type MOS transistor Q1 to be in a conducting state, in order to connect the electrical connection between the drive circuit 3 and the boost circuit 1.

As shown in FIG. 2, the drive circuit 3 further includes an N-type MOS transistor Q3 and a freewheeling diode D3. The gate of the N-type MOS transistor Q3 is connected to the negative electrode of the voltage regulator diode D2 and the other end of the resistor R2, and its drain is connected to the drain of the P-type MOS transistor Q1 and one end of the resistor R2. The negative electrode of the freewheeling diode D3 is connected to the source of the N-type MOS transistor Q3, and its positive electrode is grounded. The positive and negative electrodes of the freewheeling diode D3 are used to connect to the two ends of the contactor coil, respectively. In the illustrated embodiment, the voltage regulator diode D2 is used to drive the N-type MOS transistor Q3, so that the source voltage of the N-type MOS transistor Q3 is stable, thereby achieving the purpose of constant current.

The starting voltage provided by the drive circuit 3 to the contactor coil and the starting current of the contactor coil during the starting phase can be calculated according to the following formula: V=VD2−VQ3, I=V/R. In the formula, V is the starting voltage provided by the drive circuit 3 to the contactor coil, VD2 is the voltage on the voltage regulator diode D2, VQ3 is the threshold voltage of the N-type MOS transistor Q3, I is the starting current of the contactor coil during the starting phase, and R is the resistance of the contactor coil.

As shown in FIG. 2, the drive circuit 3 further comprises a first connection terminal P1 and a second connection terminal P2. The first connection terminal P1 is connected to the negative electrode of the freewheeling diode D3 and the source of the N-type MOS transistor Q3. The second connection terminal P2 is connected to the positive electrode of the freewheeling diode D3 and grounded. The first connection terminal P1 and the second connection terminal P2 are used to connect the two ends of the contactor coil, respectively.

As shown in FIG. 2, the drive circuit 3 further comprises a resistor R7 and a resistor R8. One end of the resistor R7 is connected to the general-purpose input/output port GPIO1 of the microcontroller 5. One end of the resistor R8 is connected to the other end of the resistor R7, and the other end is grounded. The gate of N-type MOS transistor Q4 is connected to the other end of the resistor R7 and one end of the resistor R8.

As shown in FIGS. 1-2, the contactor starting circuit further includes an LDO circuit 4. An input end of the LDO circuit 4 is connected to the power supply, and its output end is connected to the positive power supply end VDD of the microcontroller 5, for supplying power to the microcontroller 5 with a supply voltage of +5V.

As shown in FIG. 2, the LDO circuit 4 includes a low dropout linear regulator U1, capacitors C5, C3, C4, and C6. The input end of the low dropout linear regulator U1 is connected to the positive electrode of the power supply, and its output end is connected to the positive power supply end VDD of the microcontroller 5. One end of each of the capacitor C5 and capacitor C3 are connected to the input end of low dropout linear regulator U1, and the other end of each of the capacitor C5 and capacitor C3 are grounded. One end of each of the capacitor C4 and capacitor C6 are connected to the output end of low dropout linear regulator U1, and the other end of each of the capacitor C4 and capacitor C6 are grounded. The input end of the boost circuit 1 is connected to the input end of low dropout linear regulator U1.

As shown in FIG. 2, the LDO circuit 4 further includes a power supply positive electrode connection terminal P3 and a power supply negative electrode connection terminal P4. The power supply positive electrode connection terminal P3 is connected to the input end of the low dropout linear regulator U1, the input end of the boost circuit 1, and one end of each of the capacitors C5 and C3. The power supply negative electrode connection terminal P4 is connected to the other end of each of the capacitors C5 and C3. The power supply positive electrode connection terminal P3 and the power supply negative electrode connection terminal P4 are used to connect to the positive and negative electrodes of the power supply, respectively.

FIG. 2 is only an exemplary circuit diagram of the present invention, and the numerical values of each electronic component are only exemplary and can be adjusted according to actual situations. Moreover, the circuit diagram for implementing the functional block diagram shown in FIG. 1 is not limited to the circuit diagram shown in FIG. 2. In the circuit diagram shown in FIG. 2, unless otherwise specified, grounding usually refers to connecting the negative electrode of the power supply.

An exemplary embodiment of a contactor control system will now be disclosed with reference to FIGS. 1-3. The contactor control system includes the aforementioned contactor starting circuit according to FIGS. 1-2 and a contactor holding circuit 6. The contactor starting circuit is used to provide a stable starting voltage to the contactor coil, so that the contactor coil has a constant starting current during the starting phase. The duration of this constant starting current is not less than the predetermined time. The contactor holding circuit 6 is used to provide a stable holding voltage to the contactor coil after the contactor starting circuit has completed the start-up of the contactor coil, so that the contactor coil has a constant holding current during the holding phase. The holding voltage of the contactor coil during the holding phase is lower than the starting voltage of the contactor coil during the starting phase, and the holding current of the contactor coil during the holding phase is lower than the starting current of the contactor coil during the starting phase.

The contactor holding circuit 6 can ensure that the holding current of the contactor coil during the holding phase is not higher than 0.65 amperes, which can reduce energy consumption. The contactor starting circuit can ensure that the starting current of the contactor coil during the starting phase is not less than 3 amperes, which can ensure that the contactor coil can be reliably started.

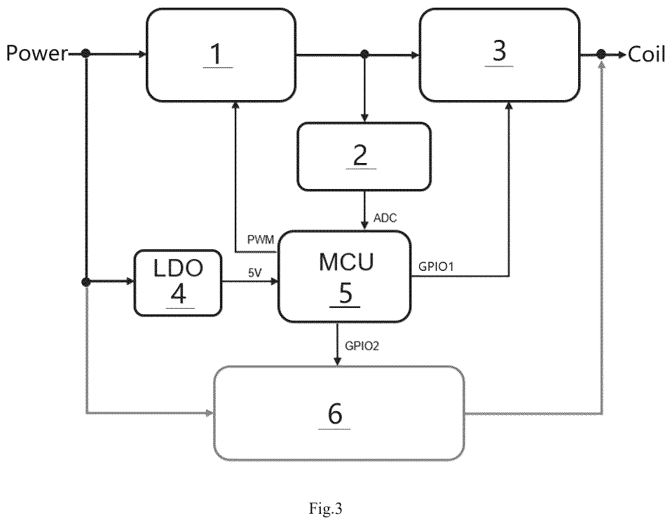

As shown in FIG. 3, the other general-purpose input/output port GPIO2 of the microcontroller 5 is connected to the contactor holding circuit 6, which is used to control the contactor holding circuit 6 to provide a stable holding voltage to the contactor coil. After the contactor starting circuit has completed the start-up of the contactor coil, the microcontroller 5 controls the boost circuit 1 to stop raising the output voltage Vout and controls the drive circuit 3 to cut off the electrical connection between the drive circuit 3 and the boost circuit 1.

In the aforementioned exemplary embodiments according to the present invention, the contactor starting circuit increases the starting current of the contactor coil by raising the power supply voltage Vin, so that the starting current of the contactor coil can reach 3A or more, expanding the application range of the contactor product.

It should be appreciated for those skilled in this art that the above embodiments are intended to be illustrative, and not restrictive. For example, many modifications may be made to the above embodiments by those skilled in this art, and various features described in different embodiments may be freely combined with each other without conflicting in configuration or principle.

Although several exemplary embodiments have been shown and described, it would be appreciated by those skilled in the art that various changes or modifications may be made in these embodiments without departing from the principles and spirit of the disclosure, the scope of which is defined in the claims and their equivalents.

As used herein, an element recited in the singular and proceeded with the word “a” or “an” should be understood as not excluding plural of said elements or steps, unless such exclusion is explicitly stated. Furthermore, references to “one embodiment” of the present invention are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

1. A contactor starting circuit, comprising:
a boost circuit increasing an input power supply voltage, an output voltage of the boost circuit is higher than the input power supply voltage;
a sampling circuit connected to an output end of the boost circuit, the sampling circuit collects the output voltage;
a drive circuit connected to the output end of the boost circuit, the drive circuit provides a stable starting voltage to a contactor coil; and
a microcontroller controlling the drive circuit based on the output voltage collected by the sampling circuit, when the output voltage reaches a predetermined voltage, the microcontroller controls the drive circuit to provide the stable starting voltage to the contactor coil, such that the contactor coil has a constant starting current during a starting phase, a duration of the constant starting current is not less than a predetermined time.

2. The contactor starting circuit of claim 1, wherein, when the output does not reach the predetermined voltage, the microcontroller controls the drive circuit to cut off an electrical connection between the output end of the boost circuit and the contactor coil, when the output voltage reaches the predetermined voltage, the microcontroller controls the drive circuit to connect the electrical connection between the output end of the boost circuit and the contactor coil.

3. The contactor starting circuit of claim 1, wherein the microcontroller controls the boost circuit based on the output voltage collected by the sampling circuit, when the output voltage does not reach the predetermined voltage, the microcontroller controls the boost circuit to continue to increase the output voltage, when the output voltage reaches the predetermined voltage, the microcontroller controls the boost circuit to stop raising the output voltage.

4. The contactor starting circuit of claim 1, wherein the contactor starting circuit ensures that a starting current of the contactor coil is not less than 3 amperes and the duration of the starting current is not less than 60 milliseconds.

5. The contactor starting circuit of claim 1, wherein the boost circuit includes:
an inductor, one end of the inductor connects to a power supply;
an N-type MOS transistor Q2, a drain of the N-type MOS transistor Q2 is connected to an other end of the inductor, a source of the N-type MOS transistor Q2 is grounded, and a gate of the N-type MOS transistor Q2 is connected to one output port of the microcontroller;
a diode D1, a positive electrode of the diode D1 is connected to the other end of the inductor and the drain of N-type MOS transistor Q2; and
a capacitor C1, one end of the capacitor C1 is connected to a negative electrode of the diode D1, an other end of the capacitor C1 is grounded, one end of the inductor is an input end of the boost circuit and one end of the capacitor C1 is an output end of the boost circuit.

6. The contactor starting circuit of claim 5, wherein a capacitance value of the capacitor C1 is calculated according to the following formula:
$$C 1 = I ⋆ T / ( Vout - Vin ) ,$$
where C1 is the capacitance value of the capacitor C1, I is a starting current of the contactor coil, T is a duration of the starting current of the contactor coil, Vout is the output voltage of the boost circuit, and Vin is the input power supply voltage.

7. The contactor starting circuit of claim 5, wherein the one output port of the microcontroller outputs PWM waves to the gate of the N-type MOS transistor Q2, to control a maximum output voltage of the boost circuit by adjusting a duty cycle of the PWM waves, the maximum output voltage is calculated according to the following formula:
$$Vmax = Vin / ( 1 - D ) ,$$
where Vmax is the maximum output voltage of the boost circuit, Vin is the input power supply voltage, and D is the duty cycle of the PWM waves.

8. The contactor starting circuit of claim 7, wherein the boost circuit further includes:
a resistor R4, one end of the resistor R4 is connected to the one output port of the microcontroller, and an other end of the resistor R4 is connected to the gate of the N-type MOS transistor Q2; and
a resistor R5, one end of the resistor R5 is connected to the one end of the resistor R4 and the one output port of microcontroller, and an other end of the resistor R5 is grounded.

9. The contactor starting circuit of claim 1, wherein the sampling circuit includes:
a resistor R1, one end of the resistor R1 is connected to the output end of the boost circuit; and
a resistor R6, one end of the resistor R6 is connected to an other end of the resistor R1, and the other end of the resistor R6 is grounded, an analog-to-digital converter of the microcontroller is connected to the other end of the resistor R1 and the one end of the resistor R6 to obtain a sampling voltage, the output voltage of the boost circuit is calculated according to the following formula:
$$Vout = V 1 ⋆ ( R 1 + R 6 ) / R 6 ,$$
where Vout is the output voltage of the boost circuit, and V1 is the sampling voltage obtained by the microcontroller.

10. The contactor starting circuit of claim 1, wherein the drive circuit includes:
a P-type MOS transistor Q1, a source of the P-type MOS transistor Q1 is connected to the output end of the boost circuit;
a resistor R3, one end of the resistor R3 is connected to the output end of the boost circuit, and an other end of the resistor R3 is connected to a gate of the P-type MOS transistor Q1;
an N-type MOS transistor Q4, a drain of the N-type MOS transistor Q4 is connected to the other end of the resistor R3 and the gate of P-type MOS transistor Q1, and a source of the N-type MOS transistor Q4 is grounded;
a resistor R2, one end of the resistor R2 is connected to the drain of the P-type MOS transistor Q1; and
a voltage regulator diode D2, a negative electrode of the voltage regulator diode D2 is connected to an other end of the resistor R2 and a positive electrode of the voltage regulator diode D2 is grounded, a general-purpose input/output port of the microcontroller is connected to the gate of the N-type MOS transistor Q4, the voltage regulator diode D2 provides a stable driving voltage.

11. The contactor starting circuit of claim 10, wherein, when the output voltage does not reach the predetermined voltage, the general-purpose input/output port outputs a low level to the gate of the N-type MOS transistor Q4, causing both the N-type MOS transistor Q4 and the P-type MOS transistor Q1 to be in a cut-off state, thereby cutting off an electrical connection between the drive circuit and the boost circuit, when the output voltage reaches the predetermined voltage, the general-purpose input/output port outputs a high level to the gate of the N-type MOS transistor Q4, causing both the N-type MOS transistor Q4 and the P-type MOS transistor Q1 to be in a conducting state to connect the electrical connection between the drive circuit and the boost circuit.

12. The contactor starting circuit of claim 11, wherein the drive circuit further includes:
an N-type MOS transistor Q3, a gate of the N-type MOS transistor Q3 is connected to the negative electrode of the voltage regulator diode D2 and the other end of the resistor R2, and a drain of the N-type MOS transistor Q3 is connected to the drain of P-type MOS transistor Q1 and the one end of the resistor R2; and
a freewheeling diode D3, a negative electrode of the freewheeling diode D3 is connected to the source of the N-type MOS transistor Q3 and a positive electrode of the freewheeling diode D3 is grounded, the positive electrode and the negative electrode of the freewheeling diode D3 are respectively connected to two ends of the contactor coil.

13. The contactor starting circuit of claim 12, wherein the stable starting voltage provided by the drive circuit to the contactor coil and a starting current of the contactor coil during the starting phase can be calculated according to the following formula:
V=VD2−VQ3, and I=V/R,
where V is the stable starting voltage provided by the drive circuit to the contactor coil, VD2 is a voltage on the voltage regulator diode D2, VQ3 is a threshold voltage of the N-type MOS transistor Q3, I is the starting current of the contactor coil during the starting phase, and R is a resistance of the contactor coil.

14. The contactor starting circuit of claim 12, wherein the drive circuit further includes:
a first connection terminal connected to the negative electrode of the freewheeling diode D3 and the source of the N-type MOS transistor Q3; and
a second connection terminal connected to the positive electrode of the freewheeling diode D3 and grounded, the first connection terminal and the second connection terminal each connect to one of the two ends of the contactor coil.

15. The contactor starting circuit of claim 11, wherein the drive circuit further includes:
a resistor R7, one end of the resistor R7 is connected to the general-purpose input/output port of the microcontroller; and
a resistor R8, one end of the resistor R8 is connected to an other end of the resistor R7, and an other end of the resistor R8 is grounded, the gate of N-type MOS transistor Q4 is connected to the other end of the resistor R7 and the one end of the resistor R8.

16. The contactor starting circuit of claim 1, further comprising an LDO circuit, an input end of the LDO circuit is connected to a power supply and an output end of the LDO circuit is connected to a positive power supply end of the microcontroller to supply power to the microcontroller.

17. The contactor starting circuit of claim 16, wherein the LDO circuit includes:
a low dropout linear regulator, an input end of the low dropout linear regulator is connected to a positive electrode of the power supply, and an output end of the low dropout linear regulator is connected to the positive power supply end of the microcontroller;
a capacitor C5 and a capacitor C3, one end of each of the capacitor C5 and the capacitor C3 are connected to the input end of the low dropout linear regulator, and an other end of each of the capacitor C5 and the capacitor C3 are grounded; and
a capacitor C4 and a capacitor C6, one end of each of the capacitor C4 and the capacitor C6 are connected to the output end of the low dropout linear regulator, and the other end of each of the capacitor C4 and the capacitor C6 are grounded, the input end of the boost circuit is connected to the input end of the low dropout linear regulator.

18. The contactor starting circuit of claim 17, wherein the LDO circuit further includes:
a power supply positive electrode connection terminal connected to the input end of the low dropout linear regulator, the input end of the boost circuit, and the one end of each of the capacitor C5 and the capacitor C3; and
a power supply negative electrode connection terminal connected to the other end of each of the capacitor C5 and the capacitor C3, the power supply positive electrode connection terminal and the power supply negative electrode connection terminal connect to a positive electrode and a negative electrode of the power supply, respectively.

19. A contactor control system, comprising:
a contactor starting circuit including a boost circuit, a sampling circuit, a drive circuit, and a microcontroller, the boost circuit increases an input power supply voltage, an output voltage of the boost circuit is higher than the input power supply voltage, the sampling circuit is connected to an output end of the boost circuit, the sampling circuit collects the output voltage, the drive circuit is connected to the output end of the boost circuit, the drive circuit provides a stable starting voltage to a contactor coil, the microcontroller controls the drive circuit based on the output voltage collected by the sampling circuit, when the output voltage reaches a predetermined voltage, the microcontroller controls the drive circuit to provide the stable starting voltage to the contactor coil, such that the contactor coil has a constant starting current during a starting phase, a duration of the constant starting current is not less than a predetermined time; and
a contactor holding circuit providing a stable holding voltage to the contactor coil after the contactor starting circuit has completed a start-up of the contactor coil, so that the contactor coil has a constant holding current during a holding phase, a holding voltage of the contactor coil during the holding phase is lower than the stable starting voltage of the contactor coil during the starting phase, a holding current of the contactor coil during the holding phase is lower than a starting current of the contactor coil during the starting phase.

20. The contactor control system of claim 19, wherein the contactor holding circuit ensures that the holding current of the contactor coil during the holding phase is not higher than 0.65 amperes, and the contactor starting circuit ensures that the starting current of the contactor coil during the starting phase is not less than 3 amperes.

21. The contactor control system of claim 19, wherein an other general-purpose input/output port of the microcontroller is connected to the contactor holding circuit for controlling the contactor holding circuit to provide the stable holding voltage to the contactor coil, after the contactor starting circuit has completed the start-up of the contactor coil, the microcontroller controls the boost circuit to stop raising the output voltage and controls the drive circuit to cut off an electrical connection between the drive circuit and the boost circuit.
